(19) United States
(12) Patent Application Publication
(10) Pub. No.: US 2016/0042949 A1
(43) Pub. Date: Feb. 11, 2016

(54) METHOD OF FORMING HIGH-RESISTIVITY REGION IN Ga2O3-BASED SINGLE CRYSTAL, AND CRYSTAL LAMINATE STRUCTURE AND SEMICONDUCTOR ELEMENT

(71) Applicants: TAMURA CORPORATION, Tokyo (JP); National Institute of Information and Communications Technology, Tokyo (JP)

(72) Inventors: Kohei SASAKI, Tokyo (JP); Masataka Higashiwaki, Tokyo (JP)

(21) Appl. No.: 14/819,206

(22) Filed: Aug. 5, 2015

(30) Foreign Application Priority Data
Aug. 6, 2014 (JP) 2014-160092

(51) Int. Cl. H01L 21/02; H01L 21/425; H01L 29/36

(52) U.S. Cl. CPC H01L 21/02694; H01L 29/36; H01L 21/425

(57) ABSTRACT

A method of forming a high-resistivity region in a Ga₂O₃-based single crystal includes ion-implanting Mg or Be into the Ga₂O₃-based single crystal, and annealing and activating the Mg or Be at a temperature of not less than 800° C. to form the high-resistivity region. A crystal laminate structure includes a Ga₂O₃-based high-resistivity crystal layer of not more than 750 nm (or 2000 nm as for Be) in thickness, the crystal layer including Mg (or Be) and a damage caused by ion implantation, and an impurity concentration inclined layer of not less than 100 nm in thickness formed under the Ga₂O₃-based high-resistivity crystal layer. The impurity concentration inclined layer includes a Mg (or Be) concentration lower than the Ga₂O₃-based high-resistivity crystal layer. The Mg (or Be) concentration is inclined in a depth direction.

The present application is based on Japanese patent application No. 2014-160092 filed on Aug. 6, 2014, the entire contents of which are incorporated herein by reference.

### BACKGROUND OF THE INVENTION

1. Field of the Invention

The invention relates to a method of forming a high-resistivity region in a Ga₂O₃-based single crystal, and a crystal laminate structure and a semiconductor element.

2. Description of the Related Art

A method for forming a p-type or high-resistivity region by acceptor ion implantation into a Ga₂O₃ single crystal is disclosed in WO 2013/035845.

WO 2013/035845 reveals that a p-type body region surrounding an n-type contact region in an n-type β-Ga₂O₃ single crystal film is formed as a high-resistivity region. WO 2013/035845 also reveals that the n-type β-Ga₂O₃ single crystal film is firstly formed, the p-type body region is then formed by ion implantation of a p-type dopant such as Mg, Be, Fe, Zn or P, etc., into the n-type β-Ga₂O₃ single crystal film, and annealing is conducted after the implantation of the p-type dopant so as to recover damage caused by implantation.

### SUMMARY OF THE INVENTION

The possibility of forming the high-resistivity region by the ion implantation depends on manufacture conditions such as ion species implanted and annealing conditions. Although WO 2013/035845 discloses various ion species to be implanted, it is silent about the manufacture conditions for forming the high-resistivity region according to the ion species.

It is an object of the invention to provide a method of forming a high-resistivity region in a Ga₂O₃-based single crystal by ion implantation, as well as a crystal laminate structure and a semiconductor element using the Ga₂O₃-based single crystal with the high-resistivity region.

As the result of detailed research, the inventors have found the relationship between types of p-type dopant and activation annealing temperature for allowing the formation of a high-resistivity region in a Ga₂O₃-based single crystal. The invention is devised based on the result.

In accordance with the invention, a method of forming a high-resistivity region in a Ga₂O₃-based single crystal defined in [1] and [2] below, a crystal laminate structure defined in [3] and [4] below, and a semiconductor element defined in [5] below are provided.

[1] A method of forming a high-resistivity region in a Ga₂O₃-based single crystal, comprising:

ion-implanting Mg or Be into the Ga₂O₃-based single crystal; and

annealing and activating the Mg or Be at a temperature of not less than 800° C. to form the high-resistivity region.

[2] The method according to [1], wherein the high-resistivity region formed comprises a concentration inclination of the Mg or Be in a depth direction.

[3] A crystal laminate structure, comprising:

a Ga₂O₃-based high-resistivity crystal layer of not more than 750 urn in thickness, the crystal layer including Mg and a damage caused by ion implantation; and

an impurity concentration inclined layer of not less than 100 nm in thickness formed under the Ga₂O₃-based high-resistivity crystal layer,

wherein the impurity concentration inclined layer comprises a Mg concentration lower than the Ga₂O₃-based high-resistivity crystal layer, and
wherein the Mg concentration is inclined in a depth direction.

[4] A crystal laminate structure, comprising:

a Ga₂O₃-based high-resistivity crystal layer of not more than 2000 nm in thickness, the crystal layer including Be and a damage caused by ion implantation; and

an impurity concentration inclined layer of not less than 100 nm in thickness formed under the Ga₂O₃-based high-resistivity crystal layer,

wherein the impurity concentration inclined layer comprises a Be concentration lower than the Ga₂O₃-based high-resistivity crystal layer, and
wherein the Be concentration is inclined in a depth direction.

[5] A semiconductor element, comprising the crystal laminate structure according to [3] or [4].

### Effects of the Invention

According to one embodiment of the invention, a high-resistivity region with high insulation property in a Ga₂O₃-based single crystal can be formed by ion implantation,

### BRIEF DESCRIPTION OF THE DRAWINGS

Next, the present invention will be explained in more detail in conjunction with appended drawings, wherein:

FIG. 1 is a schematic cross sectional view showing a Schottky-barrier diode having a high-resistivity region in a first preferred embodiment of the present invention;

FIG. 2 is a schematic cross sectional view showing a Ga₂O₃ FET having a high-resistivity region in a second embodiment;

FIGS. 3A to 3F are schematic cross sectional views showing a process of making evaluation samples;

FIGS. 4A to 4D are graphs in which reverse breakdown voltage when using various ion species is plotted relative to activation annealing temperature;

FIGS. 5A to 5C are graphs showing the relationship between annealing temperature and thermal diffusion of various ion species; and

FIG. 6 is a schematic cross sectional view showing a conventional Schottky-barrier diode.

### DETAILED DESCRIPTION OF THE PREFERRED EMBODIMENTS

Preferred embodiments of the invention will be specifically described below in conjunction with the appended drawings.

### First Embodiment

Whole Configuration of Schottky-Barrier Diode

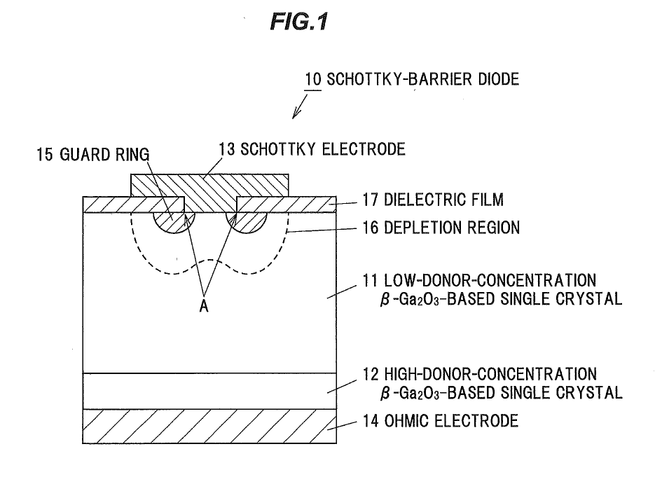

In FIG. 1, reference numeral 10 represents an entirety of a typical Schottky-barrier diode (hereinafter, simply referred to as “Schottky diode”) having a p-type high-resistivity region in the first embodiment.

Although the Schottky diode 10 is not limited to the example shown in FIG. 1, it has a low-donor-concentration β-Ga₂O₃-based single crystal 11, a high-donor-concentration β-Ga₂O₃-based single crystal 12, a Schottky electrode 13 in contact with the low-donor-concentration β-Ga₂O₃-based single crystal 11 to form a Schottky junction, an ohmic electrode 14 in contact with the high-donor-concentration β-Ga₂O₃-based single crystal 12 to form an ohmic contact, and a dielectric film 17 formed of SiO₂, Al₂O₃, AlN or SiN etc.

The β-Ga₂O₃-based single crystals 11 and 12 can include a β-Ga₂O₃ single crystal and a β-(GaₓIn_{y}Al_{z})₂O₃ single crystal (0<x≦1, 0≦y<1, 0≦z<1, x+y+z=1).

If a voltage in forward direction (a positive potential defined at the Schottky electrode) is applied to the Schottky diode 10, a forward current flows through the Schottky electrode 13 into the ohmic electrode 14. On the other hand, if a voltage in reverse direction (a negative potential defined at the Schottky electrode) is applied to the Schottky diode 10, substantially no electric current flows through the Schottky diode 10.

Configuration of Guard Ring

In order to improve the breakdown voltage of the Schottky diode 10, it is necessary to reduce an electric field concentration at an edge (which is indicated by A in the drawing) of the contact area between the Schottky electrode 13 and the low-donor-concentration β-Ga₂O₃-based single crystal 11. In the example shown in FIG. 1, a guard ring 15 having an electric field concentration relaxation structure is formed at a region corresponding to the edge of the contact area between the Schottky electrode 13 and the low-donor-concentration β-Ga₂O₃-based single crystal 11. The guard ring 15 is formed by ion implantation of a p-type impurity so as to be a p-type high-resistivity region with high insulation property.

Method of Forming the Guard Ring

The method of forming the guard ring 15 includes a step of ion-implanting a p-type impurity, Be or Mg into the low-donor-concentration β-Ga₂O₃-based single crystal 11 and a step of activating the p-type impurity by activation annealing. The guard ring 15 is thereby formed, in which the p-type impurity in the vicinity of an interface with the low-donor-concentration β-Ga₂O₃-based single crystal 11 has a concentration inclination in a depth direction (or thickness direction).

In order to prevent a decrease in breakdown voltage by the guard ring 15, it is preferred that the ion-implantation is conducted using Be (beryllium) as an ion species in a predetermined region of the low-donor-concentration β-Ga₂O₃-based single crystal 11 and the activation annealing is then conducted at a temperature of not less than 800° C. It is more preferred that the ion-implantation is conducted using Mg (magnesium) as an ion species in a predetermined region of the low-donor-concentration β-Ga₂O₃-based single crystal 11 and the activation annealing is then conducted at a temperature not less than 800° C.

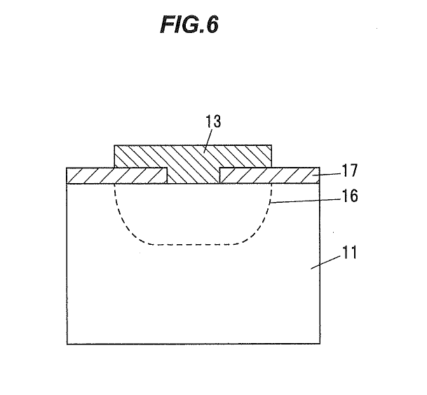

If the reverse voltage is applied to the Schottky diode 10, a depletion region 16 spreads around the outer periphery of the guard ring 15, Compared to the depletion region 16 in a conventional Schottky diode shown in FIG. 6, the depletion region 16 of the Schottky diode 10, as shown in FIG. 1, spreads thickest in a region where the guard ring 15 is formed. Thus, it is possible to reduce the electric field strength concentrating at the edge of the contact area between the Schottky electrode 13 and the low-donor-concentration β-Ga₂O₃-based single crystal 11. Also it is possible to prevent a decrease in the breakdown voltage of the Schottky diode 10 even upon application of reverse voltage and to reduce the leakage current of the Schottky diode 10.

### Effects of the First Embodiment

The first embodiment offers the following effects, in addition to the effects described above.

(1) Where the ion-implantation is conducted using Mg or Be as the ion species in the β-Ga₂O₃-based single crystal 11 and the activation annealing is then conducted for the Mg or Be at a temperature of not less than 800° C., it is possible to form the guard ring 15 with high insulation property.

(2) Due to the guard ring 15 formed, it is possible to obtain the Ga₂O₃ Schottky diode 10 with a high breakdown voltage and low loss. By using the diode 10, all power electronics devices can be reduced in energy usage.

### Second Embodiment

Whole Configuration of Ga₂O₃ FET

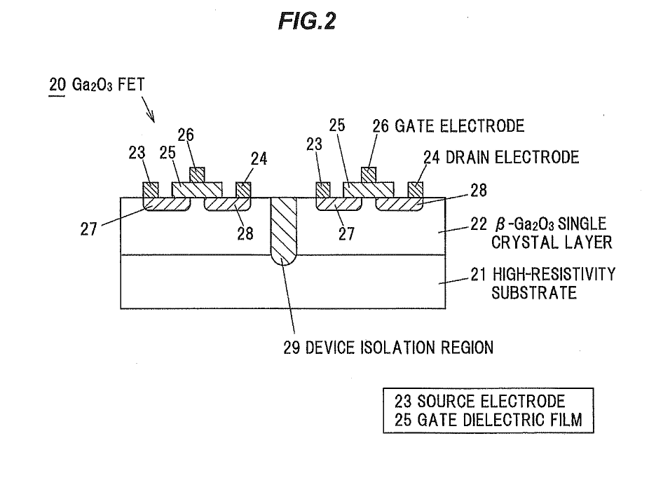

The method for forming the guard ring 15 by the ion implantation in the first embodiment is also applicable to form a device isolation region of a Ga₂O₃ FET (Field Effect Transistor) 20. FIG. 2 shows an example of the Ga₂O₃ FET 20 in the second embodiment which has a device isolation region 29 as a p-type high-resistivity region.

The Ga₂O₃ FET 20 includes a high-resistivity substrate 21 formed of a β-Ga₂O₃-based single crystal, a β-Ga₂O₃ single crystal layer 22 doped with a group IV element such as Si or Sn and formed on the high-resistivity substrate 21, a source electrode 23 and a drain electrode 24 both formed on the β-Ga₂O₃ single crystal layer 22, and a gate electrode 26 between the source electrode 23 and the drain electrode 24 on a gate dielectric film 25 which is formed on the β-Ga₂O₃ single crystal layer 22.

The Ga₂O₃ FET 20 further includes a source region 27 and a drain region 28 exposed to the surface of the β-Ga₂O₃ single crystal layer 22 and each connected to the source electrode 23 and the drain electrode 24, and the device isolation region 29 formed in the β-Ga₂O₃ single crystal layer 22 to isolate two adjacent Ga₂O₃ FETs 20.

The high-resistivity substrate 21 is a substrate formed of a β-Ga₂O₃-based single crystal doped with an acceptor impurity such as Mg, Be, Zn or Fe, e.g. a β-Ga₂O₃ single crystal or a β-(GaₓZn_{y}Al_{z})₂O₃ single crystal (0<x≦1, 0≦y<1, 0≦z<1, x+y+z=1), and has an increased resistance due to doping of the acceptor impurity.

The high-resistivity substrate 21 doped with an acceptor impurity is obtained such that an acceptor-doped β-Ga₂O₃ single crystal is grown by e.g. an EFG (Edge-defined Film-fed Growth) method and is then sliced or polished to a desired thickness.

An undoped buffer layer or a high resistivity buffer layer doped with an acceptor impurity may be formed between the high-resistivity substrate 21 and the β-Ga₂O₃ single crystal layer 22. In this case, the buffer layers can be regarded as a part of the high-resistivity substrate 21,

The source region 27 and the drain region 28 are formed by e.g. doping a donor impurity such as Si or Sn into the β-Ga₂O₃ single crystal layer 22. The doping is conducted by ion implantation or thermal diffusion.

Configuration of the Device Isolation Region

In the example shown in FIG. 2, two Ga₂O₃ FETs 20 formed of the same semiconductor material are isolated by the device isolation region 29. The device isolation region 29 has a concentration inclination of the ion-implanted p-type impurity in a depth direction.

Method of Forming the Device Isolation Region

In forming the device isolation region 29, it is preferred that the ion-implantation is conducted using Be as an ion species in a predetermined region of the β-Ga₂O₃ single crystal 22 and the activation annealing is then conducted at a temperature of not less than 800° C.

It is more preferred that the ion-implantation is conducted using Mg as an ion species in a predetermined region of the β-Ga₂O₃ single crystal 11 and the activation annealing is then conducted at a temperature not less than 800° C. Thereby, it is possible to form a device isolation region for electrically isolating plural Ga₂O₃ FETs 20 from each other.

The isolation technique of the Ga₂O₃ FETs 20 includes etching such as dry etching and wet etching and an ion implantation. In forming a trench in the β-Ga₂O₃ single crystal layer 22 by etching, due to the surface of the element being thereby roughened, the processability of a subsequent electrode-forming process etc. may lower so as to cause a decrease in production yield. In particular, the surface of the β-Ga₂O₃ single crystal layer 22 being dry-etched may be a leak path by the etching damage.

The second embodiment uses the ion implantation as the device isolation method. Thereby, elements can be isolated from each other while keeping the surface of the elements flat so as to prevent a decrease in production yield.

### Effects of the Second Embodiment

Mg or Be used as an ion species is ion-implanted into the β-Ga₂O₃ single crystal layer 22 and is then activated by annealing at a temperature of not less than 800° C. Thus, It is possible to form the device isolation region 29 with high insulation property,

The formation of the device isolation region 29 allows the multiple transistors to be collectively formed and operable on one substrate.

### EXAMPLES

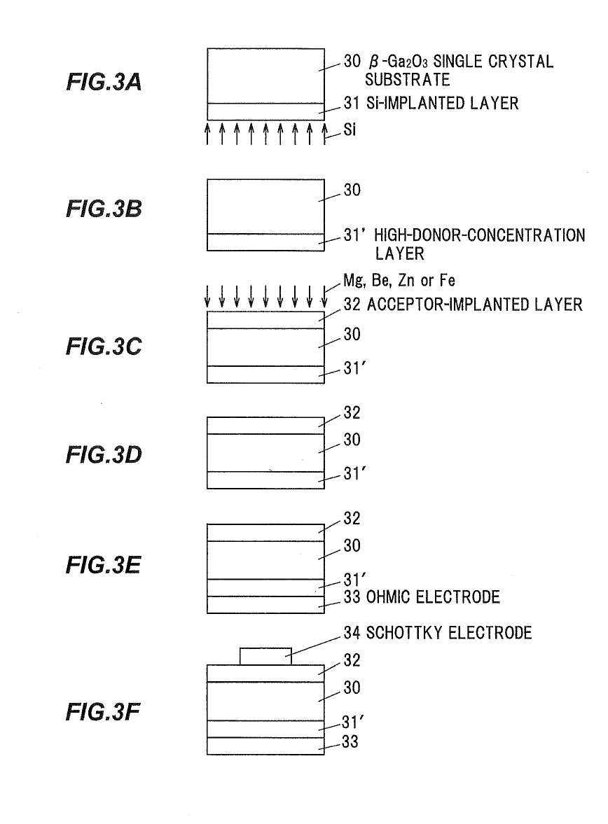

Next, the high-resistivity region of the invention will be detailed referring to Examples 1 to 4, Comparative Examples 1 to 3 and FIGS. 3 to 5C.

Manufacture of Samples for Evaluating the Insulation Property of Acceptor-Implanted Region

A 10 mm-square substrate 30 formed of an undoped β-Ga₂O₃ single crystal is used for manufacturing each of the samples. The principal surface of the β-Ga₂O₃ single crystal substrate 30 is set to be e.g. a (010) plane (hereinafter the substrate referred to as “(010) substrate 30”). The donor concentration in the (010) substrate 30 is about 2×10¹⁷ cm⁻³.

Firstly, Si is ion-implanted into the (010) substrate 30 from the back surface in multiple stages so as to allow an Si-implanted layer 31 to have a box-shaped profile of 150 nm in depth and 5×10¹⁹ cm⁻³ in concentration. After the multiple ion implantations, the activation annealing is conducted in a nitrogen atmosphere at 950° C. for 30 minutes so as to have a high-donor-concentration layer 31′. The manufacturing process is shown in FIGS. 3A and 3B.

After the activation annealing of the Si-implanted layer 31, an acceptor impurity is ion-implanted into the (010) substrate 30 from the top surface in multiple stages so as to allow an acceptor-implanted layer 32 to have a box-shaped profile of 160 nm in depth and 1×10¹⁹ cm⁻³ in concentration. Four types of acceptor ions, Mg, Be, Zn and Fe are used as the ion species.

After implanting Mg, Be, Zn and Fe, the activation annealing is conducted in a nitrogen atmosphere for 30 minutes. Activation annealing temperature is set to be 600 to 950° C. The manufacturing process is shown in FIGS. 3C and 3D. Meanwhile, it is found that most part of ion implantation damage is recovered by this activation annealing but it is difficult to completely recover the damage at any annealing temperatures.

Then, a Ti (30 nm)/Au (230 nm) ohmic electrode 33 is deposited on the back surface of the (010) substrate 30. Finally, a Pt (15 nm)/Ti (5 nm)/Au (250 nm) Schottky electrode 34 having a diameter of 200 μm is deposited on the top surface of the (010) substrate 30. The manufacturing process is shown in FIGS. 3E and 3F.

Samples doped with the four types of acceptor ions by ion implantation and then annealed at various temperatures are prepared by the manufacturing process described above. Evaluation samples without acceptor ion were also made for the purpose of comparison.

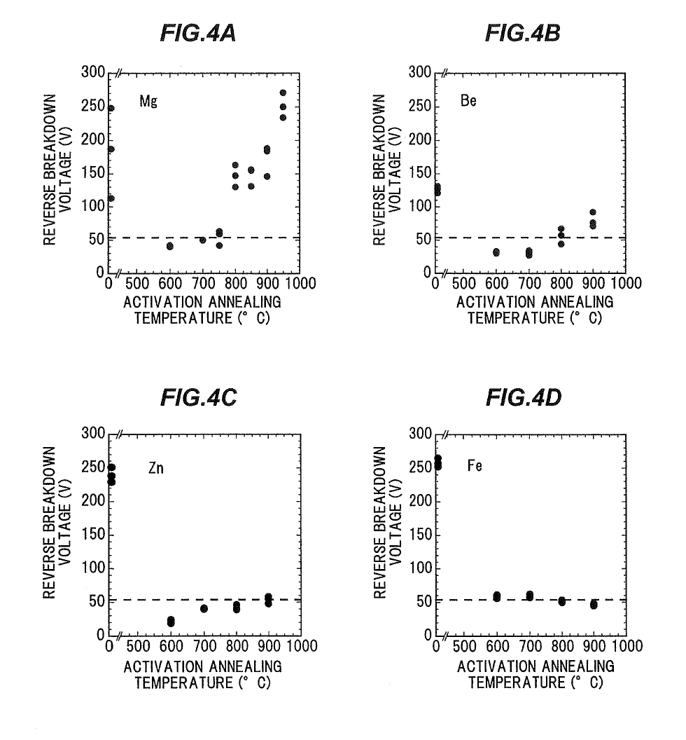

The obtained samples are evaluated concerning insulation property and reverse breakdown voltage relative to activation annealing temperature. Reverse breakdown voltage of the obtained samples was measured using a semiconductor parameter analyzer 4200-SCS from KEITHLEY. The measurement results are plotted in the graphs of FIGS. 4A to 4D in which the horizontal axis indicates activation annealing temperature and the vertical axis indicates reverse breakdown voltage. Herein, voltage (V) at a reverse current of 0.1 μA is defined as reverse breakdown voltage.

FIGS. 4A to 4D show the relationship between the activation annealing temperature and the reverse breakdown voltage in Examples 1, 2 and Comparative Examples 1 and 2.

FIG. 4A is a graph showing the reverse breakdown voltage relative to activation annealing temperature when Mg is implanted, and FIG. 4B is a graph showing the reverse breakdown voltage relative to activation annealing temperature when Be is implanted.

FIG. 4C is a graph showing the reverse breakdown voltage relative to activation annealing temperature when Zn is implanted, and FIG. 4D is a graph showing the reverse breakdown voltage relative to activation annealing temperature when Fe is implanted. In FIGS. 4A to 4D, a dotted line indicates the reverse breakdown voltage (54V) of the sample without the implantation of acceptor ion.

### Example 1

As shown in FIG. 4A, if Mg is used as the ion species, the reverse breakdown voltage increases by conducting the activation annealing at not less than 800° C. From the distribution of measurement points, it is assumed that the acceptor-implanted layer 32 is activated at not less than 800° C. and diffusion of Mg is enhanced at more than 900° C.

This proves that the acceptor-implanted layer 32 obtains a high enough resistivity. Among the four ion species of Mg, Be, Zn and Fe, the case of using Mg can offer the highest reverse breakdown voltage so as to allow the formation of a good high-resistivity region.

### Example 2

As shown in FIG. 4B, if Be is used as the ion species, the reverse breakdown voltage is lower than that of the sample without the implantation of acceptor ion (i.e., below the dotted line in FIG. 4B) when conducting the activation annealing at 600 to 700° C. However, the insulation property can be enhanced by the activation annealing at not less than 800° C. Thus, it is possible to form a better high-resistivity region than the sample without implantation of acceptor ion.

### Comparative Example 1

As shown in FIG. 4C, if Zn is used as the ion species, the reverse breakdown voltage is equal or lower than that of the sample without the implantation of acceptor ion (i.e., on or below the dotted line in FIG. 4C) at any activation annealing temperatures of 700° C., 800° C. and 900° C. even though the insulation property can be enhanced at a constant rate with an increase in activation annealing temperature. The reason for the low reverse breakdown voltage is assumed because Zn is a heavy element and the damage on the semiconductor crystal caused by the ion implantation is too severe to recover by the activation annealing.

### Comparative Example 2

As shown in FIG. 4D, if Fe is used as the ion species, there is no correlation between the activation annealing temperature and the reverse breakdown voltage. The value of reverse breakdown voltage is comparable to that of the sample without the implantation of acceptor ion (indicated by the dotted line in FIG. 4D) at any activation annealing temperatures of 700° C., 800° C. and 900° C. The reason for the low reverse breakdown voltage is assumed because Fe is a heavy element and the damage on the semiconductor crystal caused by the ion implantation is too severe to recover by the activation annealing.

As shown in Examples 1, 2 and Comparative Examples 1 and 2, it is found that the highest reverse breakdown voltage is obtained when Mg is used as an ion species. In general, a guard ring is formed by implanting an impurity ion as deep as possible, although it depends on required breakdown voltage conductance for devices. Then, Mg is implanted into a β-Ga₂O₃ single crystal by a commercially available ion implanter at the maximum implantation energy of 700 keV and breakdown voltage characteristics thereof are examined.

The method of making samples is substantially the same as the above-mentioned method of making samples to evaluate the insulation property of the acceptor-implanted region but Mg is implanted so as to provide a box-shaped profile of 750 nm in depth. As the result of examining the breakdown voltage characteristics by the same measurement device as used in Example 1 etc., the sample annealed at 950° C. exhibits a reverse breakdown voltage of 400V. Meanwhile, if the sample with an implantation depth of 160 nm is annealed at 950° C., the reverse breakdown voltage is about 250V as shown in FIG. 4A. This result proves that it is possible to enhance the reverse breakdown voltage by increasing the implantation depth.

Manufacture of Samples for Evaluating the Thermal Diffusion of Mg, Be and Zn

A 10 mm-square substrate formed of an undoped β-Ga₂O₃ single crystal is used for manufacturing each of the samples. The principal surface of the β-Ga₂O₃ single crystal substrate is set to be e.g. a (010) plane (hereinafter the substrate referred to as “(010) substrate”). The donor concentration in the (010) substrate is about 2×10¹⁷ cm⁻³.

Firstly, Mg is implanted into the (010) substrate in multiple stages so as to allow it to have a box-shaped profile of 400 nm in depth and 5×10¹⁹ cm⁻³ in concentration. After the ion implantation, four types of samples, which include three samples each annealed at 700° C., 800° C. and 900° C. and a non-annealed sample, are made.

Then, Be is implanted into the (010) substrate in multiple stages so as to allow it to have a box-shaped profile of 500 nm in depth and 1×10¹⁹ cm⁻³ in concentration. After the ion implantation, four types of samples, which include three samples each annealed at 700° C., 800° C. and 900° C. and a non-annealed sample, are made.

Finally, Zn is implanted into the (010) substrate in in multiple stages so as to allow it to have a box-shaped profile of 500 nm in depth and 1×10¹⁹ cm⁻³ in concentration. After the ion implantation, four types of samples, which include samples each annealed at 700° C., 800° C. and 900° C. and a non-annealed sample, are made.

Thus, twelve types of samples are made in total.

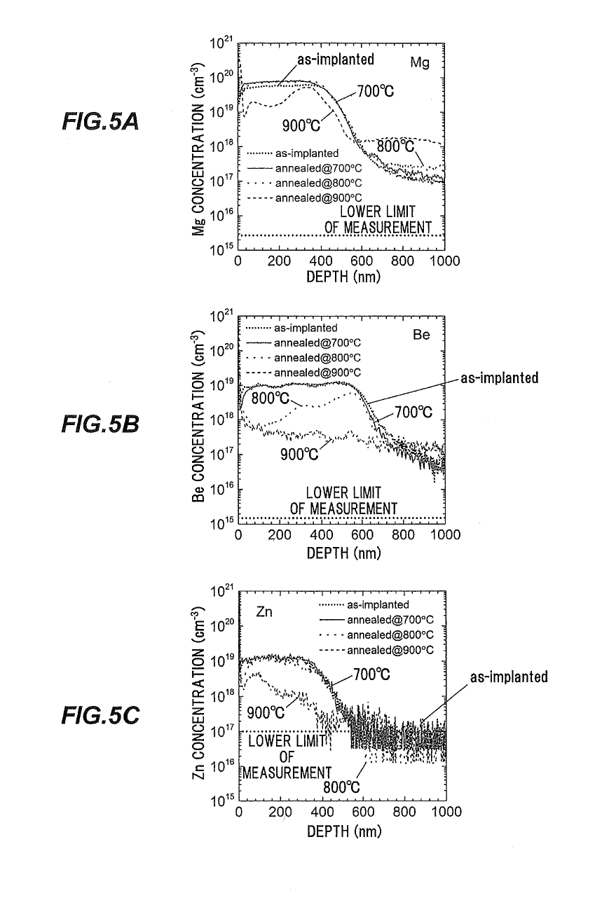

FIGS. 5A to 5C show the relationship between activation annealing temperature and the thermal diffusion in Examples 3, 4 and Comparative Example 3.

A variation in a Mg concentration (cm⁻³) relative to a depth (nm) when annealed at temperatures of 700° C., 800° C. and 900° C. is plotted in FIG. 5A, and a variation in a Be concentration (cm⁻³) relative to a depth (nm) when annealed at temperatures of 700° C., 800° C. and 900° C. is plotted in FIG. 5B.

A variation in a Zn concentration (cm⁻³) relative to a depth (nm) when annealed at temperatures of 700° C., 800° C. and 900° C. is plotted in FIG. 5C. In FIGS. 5A to 5C, a curved line indicating the concentration distribution of acceptor ion in a non-annealed sample (i.e., as-implanted) is shown as Comparative Example.

### Example 3

As shown in FIG. 5A, the Mg concentration in the (010) substrate varies inclining in the depth direction in a region at a depth of 400 to 700 nm from the surface of the (010) substrate. When a Mg-doped layer is formed by ion implantation, the thickness of a region having the Mg concentration inclination is at least 100 nm.

By contrast, if the Mg-doped layer is formed epitaxially growing a Ga₂O₃ single crystal while adding Mg by a thin-film growth method such as MBE and HVPE, the Mg concentration inclination region (or layer) is not formed. Thus, the formation of the Mg concentration inclined layer is one of the features of the invention.

As shown in FIG. 5A, the thermal diffusion of Mg is intensified by the activation annealing at not less than 900° C. Thus, the activation annealing is conducted preferably at 800 to 850° C. if desired to activate Mg without changing the Mg concentration profile produced immediately after the ion implantation. Since Mg can be activated without destroying the concentration profile produced immediately after the ion implantation, it has higher degree of freedom in device design than the other three types of ion species, Be, Zn and Fe.

### Example 4

As shown in FIG. 5B, the Be concentration in the (010) substrate varies inclining in the depth direction in a region at a depth of 500 to 800 nm from the surface of the (010) substrate. When a Be-doped layer is formed by ion implantation, the thickness of a region having the Be concentration inclination is at least 100 nm.

by contrast, if the Be-doped layer is formed epitaxially growing a Ga₂O₃ single crystal while adding Be by a thin-film growth method such as MBE and HVPE, the Be concentration inclination region (or layer) is not formed. Thus, the formation of the Be concentration inclined layer is one of the features of the invention.

As shown in FIG. 5B, if Be is used as the ion species, the thermal diffusion of Be in the ion implantation damage region is intensified by the activation annealing at not less than 800° C.

Comparing Mg with Be, the reverse breakdown voltage increases by the activation annealing at not less than 800° C. as for both Mg and Be, but the concentration profile does not change up to 900° C. for Mg. By contrast, the thermal diffusion of Be is intensified at 800° C. or higher. Thus, it is not possible to activate Be without destroying the concentration profile produced immediately after the ion implantation but this fact does not hinder the use of Be in the invention.

### Comparative Example 3

As shown in FIG. 5C, if Zn is used as the ion species, the thermal diffusion of Zn in the ion implantation damage region is intensified by the activation annealing at not less than 900° C. Since it is not possible to activate Zn without destroying the concentration profile produced immediately after the ion implantation and the reverse breakdown voltage is low, it is not possible to form a good high-resistivity region in Comparative Example 3.

Comparison of Implantation Depth and Implantations Energy Among Mg, Be, Zn and Fe

The relationship between implantation energy and implantation depth is researched for Mg, Be, Zn and Fe. When monovalent Mg is implanted into β-Ga₂O₃ by a general ion implanter at the maximum implantation energy of 350 keV, the maximum concentration is observed at a depth of about 400 nm from the surface of the (010) substrate. When divalent Mg is implanted into β-Ga₂O₃ by the general implanter at the maximum implantation energy of 700 keV, the maximum concentration is observed at a depth of about 750 nm from the surface of the (010) substrate. When monovalent Zn is implanted into β-Ga₂O₃ by the general ion implanter at the maximum implantation energy of 350 keV, the maximum concentration is observed at a depth of about 140 nm from the surface of the (010) substrate. When divalent Zn is implanted into β-Ga₂O₃ by the general implanter at the maximum implantation energy of 700 keV, the maximum concentration is observed at a depth of about 300 nm from the surface of the (010) substrate. When monovalent Fe is implanted into β-Ga₂O₃ by the general ion implanter at the maximum implantation energy of 350 keV, the maximum concentration is observed at a depth of about 160 nm from the surface of the (010) substrate. When divalent Fe is implanted into β-Ga₂O₃ by the general ion implanter at the maximum implantation energy of 700 keV, the maximum concentration is observed at a depth of about 300 nm from the surface of the (010) substrate.

By contrast, it is found that, when implanting monovalent Be into β-Ga₂O₃, it is possible to have the maximum concentration at a depth of about 500 nm from the surface of the (010) substrate at an energy of 180 keV which is about half the energy used in three of the above-mentioned conditions. When implanting monovalent Be by the general ion implanter at the maximum energy of 350 keV, it is possible to have the maximum concentration at a depth of about 1000 nm. Furthermore, when implanting divalent Be by the general ion implanter at the maximum energy of 700 keV, it is possible to have the maximum concentration at a depth of about 2000 nm.

Among the four ion species (Mg, Be, Zn and Fe), Be can be implanted deepest by using the lowest implantation energy. When the guard ring etc. of a Schottky diode is formed by the acceptor ion implantation, the deeper it is implanted the higher the effect of the guard ring becomes. Thereby, the reverse breakdown voltage of the device can be enhanced. Thus, high device characteristics can be obtained by using Be in forming the high-resistivity region by the ion implantation.

Evaluation Results

The results of Examples 1 to 4 and Comparative Examples 1 to 3 prove that it is possible to form a high-resistivity region with high insulation property by using Mg or Be as the ion species, ion-implanting Mg or Be, then activating the ion-implanted Mg or Be by annealing at not less than 800° C.

It will be appreciated that the above-mentioned method of forming a high-resistivity region in a Ga₂O₃-based single crystal can offer: a semiconductor element provided with a crystal laminate structure which includes a Ga₂O₃-based high-resistivity crystal layer of not more than 750 nm in thickness and an impurity concentration inclined layer of not less than 100 nm in thickness located under the Ga₂O₃-based high-resistivity crystal layer such that the Ga₂O₃-based high-resistivity crystal layer has the substantially uniform Mg concentration and ion implantation damage and the impurity concentration inclined layer has a Mg concentration lower than the Ga₂O₃-based high-resistivity crystal layer and has a Mg concentration inclined in the depth direction: and a semiconductor element provided with a crystal laminate structure which includes a Ga₂O₃-based high-resistivity crystal layer of not more than 2000 nm in thickness and an impurity concentration inclined layer of not less than 100 nm in thickness located under the

Ga₂O₃-based high-resistivity crystal layer such that the Ga₂O₃-based high-resistivity crystal layer has the substantially uniform Be concentration and ion implantation damage and the impurity concentration inclined layer has a Be concentration lower than the Ga₂O₃-based high-resistivity crystal layer and has a Be concentration inclined in the depth direction.

For example, the Ga₂O₃-based high-resistivity crystal layer and the impurity concentration inclined layer mentioned above correspond to, in the Schottky diode 10 of the first embodiment, a part of the guard ring 15 having the substantially uniform Mg or Be concentration and a bottom part of the guard ring 15 having the Mg or Be concentration decreasing along a depth direction, respectively, and correspond to, in the Ga₂O₃ FET 20 of the second embodiment, a part of the device isolation region 29 having the substantially uniform Mg or Be concentration and a bottom part of the device isolation region 29 having the Mg or Be concentration decreasing along a depth direction, respectively.

Meanwhile, the impurity concentration inclined layer is, as mentioned above, to be formed by ion-implanting Mg or Be into the Ga₂O₃-based crystal layer so as to form a Ga₂O₃-based high-resistivity crystal layer, but it is not to be formed when the Ga₂O₃-based high-resistivity crystal layer is formed by introducing Mg or Be simultaneously with the growth of the Ga₂O₃-based crystal layer.

The ion implantation damage in the Ga₂O₃-based high-resistivity crystal layer is caused by the ion implantation of Mg or Be and remains without being completely recovered even though it can be reduced by the activation annealing after the ion implantation.

Since the impurity concentration inclined layer is also formed by the ion implantation of Mg or Be, it must have the ion implantation damage. However, since the concentration of Mg or Be implanted into the impurity concentration inclined layer is lower than that of the Ga₂O₃-based high-resistivity crystal layer and for other reasons, the ion implantation damage in the impurity concentration inclined layer is less than that in the Ga₂O₃-based high-resistivity crystal layer.

In addition, the Ga₂O₃-based high-resistivity crystal layer and the impurity concentration inclined layer are formed in the same ion implantation process and are thus formed serially in position.

As shown in FIGS. 4A to 4D, immediately after the ion implantation, the acceptor-implanted layer or region before conducting the activation annealing has a high resistance even when using any one of Mg, Be, Zn and Fe as the ion species since semiconductor crystal in the ion-implanted region is broken or damaged. Especially when using Zn and Fe, since the semiconductor crystal is greatly damaged, a high insulation property can be obtained. Thus, a manufacturing method without conducting activation annealing is also available as the high-resistivity region forming method. In case of using this method, however, damage on the semiconductor crystal in the ion-implanted region may be recovered over time, causing a decrease in the reverse breakdown voltage.

The manufacturing method of forming the high-resistivity region without conducting the activation annealing after the acceptor ion implantation may be useful for short-product life devices. However, for long-product life devices, it is preferable to conduct the activation annealing after the acceptor ion implantation.

Although the exemplary embodiments, Examples, Comparative Examples and drawings of the invention have been described, it is obvious that the invention according to claims is not to be limited thereto. Thus, it should be noted that all combinations of the features described in the embodiments etc. are not necessary to solve the problem of the invention.

What is claimed is:

1. A method of forming a high-resistivity region in a Ga₂O₃-based single crystal, comprising:
ion-implanting Mg or Be into the Ga₂O₃-based single crystal; and
annealing and activating the Mg or Be at a temperature of not less than 800° C. to form the high-resistivity region.

2. The method according to claim 1, wherein the high-resistivity region formed comprises a concentration inclination of the Mg or Be in a depth direction.

3. A crystal laminate structure, comprising;
a Ga₂O₃-based high-resistivity crystal layer of not more than 750 nm in thickness, the crystal layer including Mg and a damage caused by ion implantation; and
an impurity concentration inclined layer of not less than 100 nm in thickness formed under the Ga₂O₃-based high-resistivity crystal layer,
wherein the impurity concentration inclined layer comprises a Mg concentration lower than the Ga₂O₃-based high-resistivity crystal layer, and
wherein the Mg concentration is inclined in a depth direction.

4. A crystal laminate structure, comprising:
a Ga₂O₃-based high-resistivity crystal layer of not more than 2000 nm in thickness, the crystal layer including Be and a damage caused by ion implantation; and
an impurity concentration inclined layer of not less than 100 nm in thickness formed under the Ga₂O₃-based high-resistivity crystal layer,
wherein the impurity concentration inclined layer comprises a Be concentration lower than the Ga₂O₃-based high-resistivity crystal layer, and
wherein the Be concentration is inclined in a depth direction.

5. A semiconductor element, comprising the crystal laminate structure according to claim 3.

6. A semiconductor element, comprising the crystal laminate structure according to claim 4.
